(19) United States
(12) Patent Application Publication
(10) Pub. No.: US 2008/0288263 A1
(43) Pub. Date: Nov. 20, 2008

(54) Method and Apparatus for Encoding/Decoding

(75) Inventors: Yang-Won Jung, Seoul (KR); Hee Suk Pang, Seoul (KR); Hyen-O Oh, Gyeonggi-do (KR); Dong Soo Kim, Seoul (KR); Jae Hyun Lim, Seoul (KR)

Correspondence Address: FISH & RICHARDSON P.C., PO BOX 1022, MINNEAPOLIS, MN, 55440-1022, US

(73) Assignee: LG ELECTRONICS, INC., Seoul (KR)

(21) Appl. No.: 12/067,026

(22) PCT Filed: Sep. 14, 2006
(86) PCT No.: PCT/KR2006/003658

§ 371 Date: Jun. 9, 2008

Related U.S. Application Data
(60) Provisional application No. 60/716,525, filed on Sep. 14, 2005.

(30) Foreign Application Priority Data
Jul. 28, 2006 (KR) 10-2006-0071752

(51) Int. Cl. H03M 7/30

(52) U.S. Cl. 704/500; 704/E19.005

(57) ABSTRACT

An encoding method and apparatus and a decoding method and apparatus are provided. The encoding method includes encoding data, generating a data bit array comprising the encoded data and encoding information, and generating an align bit array comprising one or more Is. According to the encoding method and apparatus and the decoding method and apparatus, it is possible to enhance the quality of decoded data by inserting various information into an align bit array that is included in a bitstream for aligning a plurality of encoded data bit arrays with one another. In addition, according to the encoding method and apparatus and the decoding method and apparatus, it is possible to efficiently utilize data bandwidths that are allocated for the encoding/decoding of data at low bitrates by enhancing the efficiency of data encoding.

### TECHNICAL FIELD

The present invention relates to an encoding method and apparatus and a decoding method and apparatus, and more particularly, to an encoding method and apparatus which can generate a bitstream using encoded data and encoding information, and a decoding method and apparatus which can receive a bitstream and decode the received bitstream.

### BACKGROUND ART

As multimedia that deals with audio, video, and text data becomes commonplace, more public attention has been drawn to techniques of compressing and encoding audio, video, and text data into a bitstream and transmitting the bitstream and techniques of receiving a bitstream, restoring audio, video, and text data from the received bitstream through decoding, and reproducing the audio, video, and text data.

Typical data encoding methods will hereinafter be described in detail focusing on conventional audio signal encoding methods.

First of all, time-domain audio signals are converted into frequency-domain signals. According to the human psychoacoustic model, the properties of frequency-domain audio signals that can be perceived by the human ears considerably vary from one frequency band to another, whereas the properties of time-domain audio signals that can be perceived by the human ears do not vary as much. Therefore, the efficiency of data compression can be enhanced by varying the number of bits allocated from one frequency band to another.

As for frequency-domain audio signals, a masking threshold is calculated for each frequency band by utilizing the masking phenomenon. Then, signal processing is performed on the frequency-domain audio signals using the masking threshold in order to minimize variations in the quality of sound of the frequency-band audio signals that are perceived by the human ears and to enhance the efficiency of encoding.

Then, the frequency-domain audio signals are scalar-quantized so that the size of quantization noise for each frequency band is smaller than the masking threshold and that the quantization noise cannot be perceived by the human ears. Thereafter, the scalar-quantized audio signals and encoding information are combined, thereby generating a bitstream having a predefined format.

When data is encoded/decoded using conventional data encoding/decoding methods, a bitstream obtained by the encoding may include unnecessary bit arrays that do not include any necessary decoding information that can be used to decode the bitstream, thereby reducing the efficiency of encoding/decoding. This problem of conventional data encoding/decoding methods is apparent especially in the situation when data is encoded at low bitrates and causes a decrease in the efficiency of encoding and deterioration of the quality of decoded data.

### DISCLOSURE OF INVENTION

### Technical Problem

The present invention provides an encoding method and apparatus and a decoding method and apparatus which can enhance encoding/decoding efficiency by generating a bitstream including only information that is needed to decode the bitstream.

### Technical Solution

According to an aspect of the present invention, there is provided an encoding method. The encoding method includes encoding data, generating a data bit array comprising the encoded data and encoding information, and generating an align bit array comprising one or more 1s.

According to another aspect of the present invention, there is provided a decoding method of receiving a bitstream and decoding the bitstream. The decoding method includes extracting a data bit array comprising encoded data and encoding information from the bitstream, extracting an align bit array comprising one or more 1s from the bitstream, and decoding the extracted data bit array using information included in the extracted align bit array.

According to another aspect of the present invention, there is provided a decoding method of receiving a bitstream and decoding the bitstream. The decoding method includes extracting a data bit array comprising encoded data and encoding information from the bitstream, extracting a flag indicating whether an align bit array comprises information from the bitstream, and if the flag has a value of 1, extracting an align bit array from the bitstream and decoding the extracted data bit array using information included in the extracted align bit array.

According to another aspect of the present invention, there is provided an encoding apparatus. The encoding apparatus includes an encoding unit which encodes data, and a bitstream generation unit which generates a bitstream using the encoded data, and the bitstream generation unit includes a data bit array generation unit which generates a data bit array comprising the encoded data and encoding information, and an align bit array generation unit which generates an align bit array comprising one or more 1s.

According to another aspect of the present invention, there is provided a decoding apparatus of receiving a bitstream and decoding the bitstream. The decoding apparatus includes a data bit array extraction unit which extracts a data bit array comprising encoded data and encoding information from the bitstream, an align bit array extraction unit which extracts an align bit array comprising one or more 1s (OK?) from the bitstream, and a decoding unit which decodes the extracted data bit array using information included in the extracted align bit array.

According to another aspect of the present invention, there is provided a data structure of a bitstream comprising encoded data. The data structure includes a frame data field which comprises the encoded data and encoding information as frames, a byte align field which comprises an align bit array that comprises one or more 1s, and a flag which indicates whether the align bit array comprises information.

According to another aspect of the present invention, there is provided a computer-readable recording medium having recorded thereon a program for executing one of the encoding method and the decoding methods.

### Advantageous Effects

According to the encoding method and apparatus and the decoding method and apparatus, it is possible to enhance the quality of decoded data by inserting various information into an align bit array that is included in a bitstream for aligning a plurality of encoded data bit arrays with one another. In addition, according to the encoding method and apparatus and the decoding method and apparatus, it is possible to efficiently utilize data bandwidths that are allocated for the encoding/decoding of data at low bitrates by enhancing the efficiency of data encoding.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of an encoding apparatus according to an embodiment of the present invention;

FIG. 2 is a diagram illustrating a data structure of a bitstream according to an embodiment of the present invention;

FIG. 3 is a flowchart illustrating an encoding method according to an embodiment of the present invention;

FIG. 4 is a block diagram of a decoding apparatus according to an embodiment of the present invention;

FIG. 5 is a flowchart illustrating a decoding method according to an embodiment of the present invention;

FIG. 6 is a block diagram of a multi-channel audio signal encoding/decoding system according to an embodiment of the present invention;

FIG. 7 is a block diagram of a multi-channel audio signal encoding apparatus according to an embodiment of the present invention; and

FIG. 8 is a block diagram of a multi-channel audio signal decoding apparatus according to an embodiment of the present invention.

### BEST MODE FOR CARRYING OUT THE INVENTION

The present invention will now be described more fully with reference to the accompanying drawings in which exemplary embodiments of the invention are shown.

FIG. 1 is a block diagram of an encoding apparatus according to an embodiment of the present invention. Referring to FIG. 1, the encoding apparatus includes an encoding unit 100 and a bitstream generation unit 110. The bitstream generation unit 110 includes a data bit array generation unit 120, an align bit quantity determination unit 130, and an align bit array generation unit 140. An operation of the encoding apparatus illustrated in FIG. 1 will hereinafter be described in detail with reference to FIG. 3.

Referring to FIG. 3, in operation 300, the encoding unit 100 encodes data by performing a predetermined encoding operation. Examples of the data include all kinds of data that can be compressed such as audio data, video data, and text data. A variety of encoding methods can be used in operation 300. Also, nearly all kinds of data compression methods can be used in operation 300. For example, an MPEG Surround Spatial Audio Coding (SAC) encoding method can be used in operation 300.

The bitstream generation unit 110 generates a bitstream using the encoded data and encoding information.

In detail, in operation 310, the data bit array generation unit 120 of the bitstream generation unit 110 generates a data bit array comprising the encoded data and encoding information.

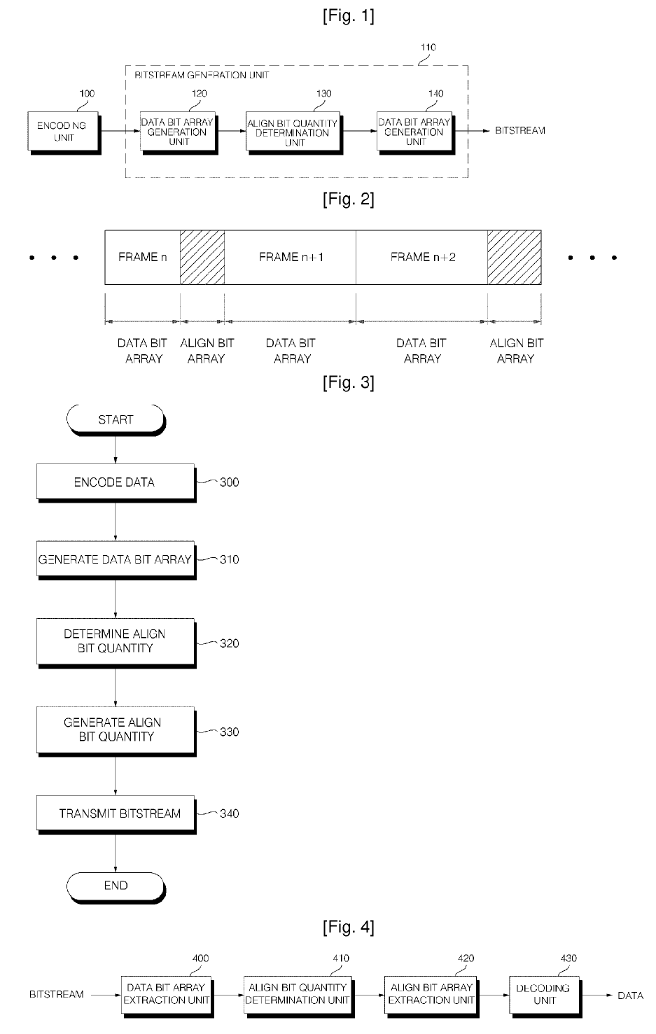

FIG. 2 is a diagram illustrating a data structure of a bitstream according to an embodiment of the present invention. Referring to FIG. 2, the bitstream comprises a series of a plurality of frames, which are minimum units of decoding). A plurality of bit arrays respectively corresponding to the frames are sequentially arranged in units of predefined bit units, and preferably, in units of bytes (1 byte=8 bits). Accordingly, if the number of bits in a data bit array of a frame, which comprises encoded data and encoding information, is a multiple of the number of bits in one predefined bit unit, and preferably, a multiple of the number of bits in one byte (i.e., a multiple of 8), then an align bit array may be inserted into the bitstream behind the data bit array so that the frame can become a number of predefined bit units long.

Referring to FIG. 3, in operation 320, the align bit quantity determination unit 130 determines an align bit quantity indicating the number of bits to be included in an align bit array based on the number of bits in the data bit array generated in operation 310. The align bit quantity determination unit 130 may determine the difference between the number of bits allocated to the data bit array generated in operation 310 and the number of bits in the data bit array generated in operation 310 as the align bit quantity.

In the case of a bitstream comprising config data that is followed by a bit array of each frame, an align bit array comprising a number of bits corresponding to an align bit quantity determined in the aforementioned manner by the align bit quantity determination unit 130 may be inserted into the bitstream behind the configuration data.

Referring to FIG. 2, if the number of bits in a data bit array of a frame (e.g., frame n or frame n+2) is not a multiple of the number of bits in one predefined bit unit (preferably, a multiple of 8, an align bit array comprising a number of bits corresponding to the difference between the number of bits in the data bit array and the least multiple of 8 greater than the number of bits in the data bit array may be inserted into a bitstream behind the data bit array. For example, if the number of bits in a data bit array of frame n is 27, then an align bit array comprising a number of bits corresponding to the difference between 27 and 32, which is the least multiple of 8 greater than 27, i.e., an align bit array comprising five bits, is transmitted after the transmission of the data bit array corresponding to frame n.

If the number of bits in a data bit array of each frame (e.g., frame n+1) is a multiple of the number of bits in one predefined bit unit, and preferably, a multiple of 8, no align bit array needs to be inserted into a bitstream.

A bitstream may include a flag which comprises information indicating whether an align bit array of a frame in the bitstream includes information. For example, if an align bit array of a frame includes information, then the flag may have a value of 1. On the other hand, if an align bit array of a frame does not include any information and is simply filled with one or more 0s, then the flag may have a value of 0. This flag may be inserted into a frame header that is followed by a bit array corresponding to each frame in a bitstream.

If the flag has a value of 0, then an align bit array of a frame is filled with as many 0s as the number of bits in the align bit array.

A decoding apparatus can determine based on the flag whether an align bit array includes information, and can thus determine whether to use the align bit array in a decoding operation.

Referring to FIG. 3, in operation 330, the align bit array generation unit 140 generates an align bit array comprising a number of bits corresponding to the align bit quantity determined in operation 320. The align bit array generated in operation 320 may be comprised of a bit array having one or more 1s and may include information that is needed to perform a decoding operation.

In operation 340, the data bit array generated in operation 310 and the align bit array generated in operation 330 are transmitted consecutively in units of frames.

Examples of information that can be included in an align bit array will hereinafter be described in detail.

First of all, information that is generated during the encoding of each frame may be included in an align bit array. According to an embodiment of the present invention, encoded data that is obtained by the encoding unit 100 and cannot included in a data bit array due to, for example, limited transmission bitrates, may be included in an align bit array that follows the data bit array. Preferably, encoded data that is obtained by the encoding unit 100 and is not included in a data bit array is stored in a storage unit (not shown). Assuming that the align bit quantity determined by the align bit quantity determination unit 130 is more than one, encoded data that is stored in the storage unit and can be represented by a number of bits corresponding to the align bit quantity determined by the align bit quantity determination unit 130 is included in an align bit array.

For example, referring to FIG. 2, if not all encoded data that is obtained by the encoding unit 100 regarding frame n or frame n+2 can be included in a data bit array corresponding to frame n or frame n+2, as much encoded data as can be represented by a number of bits in an align bit array that follows the data bit array may be included in the align bit array.

Information other than the information generated during the encoding of each frame can also be included in an align bit array.

According to another embodiment of the present invention, additional information regarding a bitstream to be transmitted, for example, metadata or watermark data for copy protection may be included in an align bit array. Examples of metadata regarding audio data include a file name, title information, genre information, and lyric information. Preferably, the additional information may be created before the creation of the bitstream to be transmitted or during the creation of the bitstream to be transmitted and may be stored in a storage unit (not shown). Thereafter, whenever a frame whose align bit quantity is determined to be one or more than one is encountered, the additional information may be inserted in an align bit array of the frame, and then the bitstream to be transmitted may be transmitted.

According to another embodiment of the present invention, information upon which an encoding apparatus and a decoding device have agreed in advance, for example, error check data that is needed to determine whether transmission errors have occurred, may be included in an align bit array. Preferably, a storage unit (not shown) which stores a bit-pattern table that matches an align bit quantity to error check data may be searched for error check data corresponding to the number of bits in an align bit array of a current frame, and the identified error check data may be included in an align bit array corresponding to the current frame. A decoding apparatus may store the same bit-pattern table as the bit-pattern table present in the storage unit.

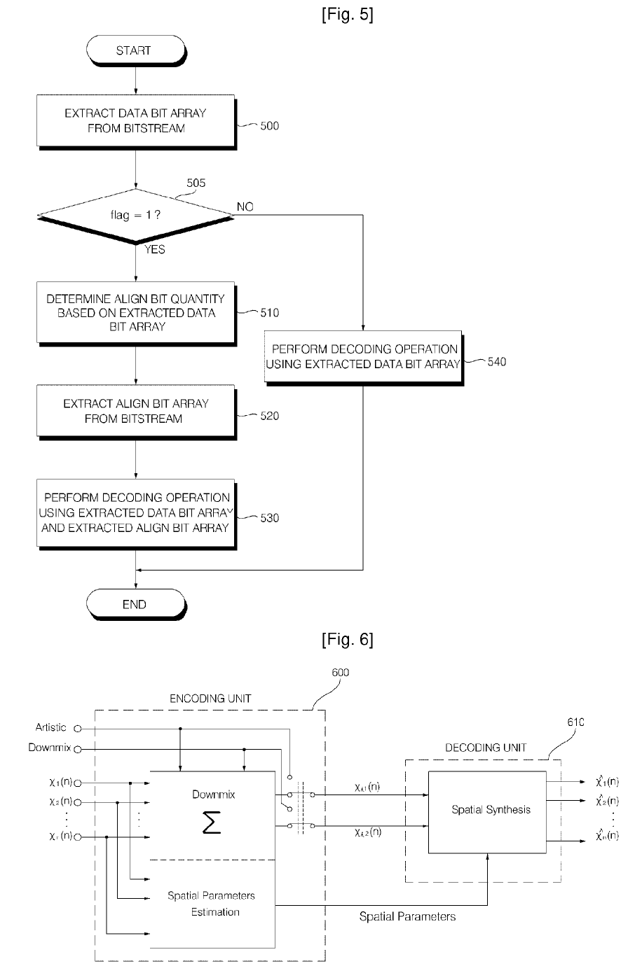

FIG. 4 is a block diagram of a decoding apparatus according to an embodiment of the present invention. Referring to FIG. 4, the decoding apparatus includes a data bit array extraction unit 400, an align bit quantity determination unit 410, an align bit array extraction unit 420, and a decoding unit 430. An operation of the decoding apparatus illustrated in FIG. 4 will hereinafter be described in detail with reference to FIG. 5. FIG. 5 is a flowchart illustrating a decoding method according to an embodiment of the present invention.

Referring to FIG. 5, in operation 500, the data bit array extraction unit 400 extracts, from an input bitstream, a data bit array and a flag indicating whether an align bit array that is included in the input bitstream includes information.

In operation 505, it is determined whether the extracted flag has a value of 1. If it is determined in operation 505 that the extracted flag has a value of 1, then it appears that the align bit array of the input bitstream include information that can be used to perform a decoding operation. Thus, decoding can be performed later using the extracted data bit array and the information included in the align bit array of the input bitstream.

In detail, in operation 510, if it is determined in operation 505 that the extracted flag has a value of 1, then the aligned bit quantity determination unit 410 determines an align bit quantity based on the number of bits in the extracted data bit array. The determination of the align bit quantity has already been described above with reference to FIGS. 1 and 2, and thus, a detailed description thereof will be skipped.

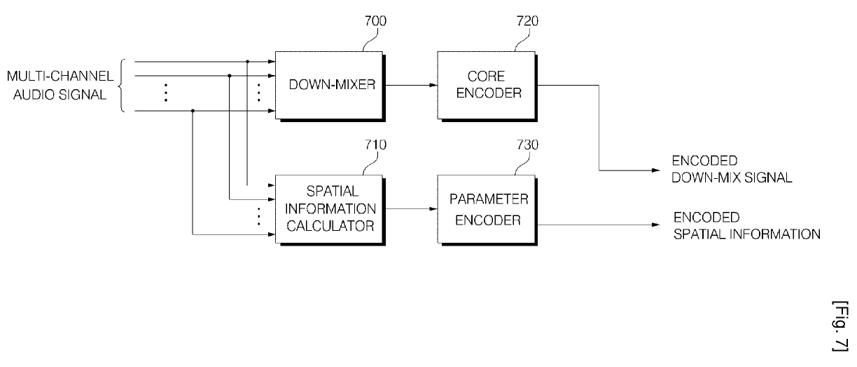

In operation 520, the align bit array extraction unit 420 extracts an align bit array comprising a number of bits corresponding to the align bit quantity determined in operation 510 from the input bitstream. In operation 530, the decoding unit 430 performs a decoding operation in units of frames using the extracted data bit array and the extracted align bit array. Nearly all kinds of decoding methods can be used in operation 530. For example, an MPEG Surround SAC decoding method can be used in operation 530. The MPEG Surround SAC decoding method will be described later in detail with reference to FIGS. 6 and 8.

The extracted align bit array may include information. In this case, the decoding apparatus may define a variety of types of information that can be included in the extracted align bit array in advance. Examples of the information that can be included in the extracted align bit array are as follows.

First of all, information that is generated during the encoding of each frame of the input bitstream may be included in an align bit array. According to an embodiment of the present invention, encoded data obtained by the encoding unit encoded data that is obtained by the encoding unit 100 illustrated in FIG. 1 and cannot be included in a data bit array due to, for example, limited transmission bitrates, may be included in an align bit array that follows the data bit array. In this case, the decoding unit 430 performs a decoding operation by adding the encoded data included in the align bit array to the encoded data included in the data bit array.

Information other than the information generated during the encoding of each frame can also be included in an align bit array. According to another embodiment of the present invention, additional information regarding a bitstream to be transmitted, for example, metadata or watermark data for copy protection may be included in an align bit array. Preferably, whenever an align bit array of a frame is encountered, data included in the align bit array is stored. When the amount of the stored data reaches a predetermined level, the stored data can be used as metadata or watermark data.

According to another embodiment of the present invention, information upon which an encoding apparatus and a decoding device have agreed in advance, for example, error check data that is needed to determine whether transmission errors have occurred, may be included in an align bit array. Preferably, a storage unit (not shown) which stores a bit-pattern table that matches an align bit quantity to error check data may be searched for error check data corresponding to the number of bits in the extracted align bit array. Then, the identified error check data may be compared with error check data included in the extracted align bit array. If the identified error check data and the error check data included in the extracted align bit array match, then it may be determined that no transmission error has occurred during the transmission of a data bit array that is followed by the extracted align bit array.

Referring to FIG. 5, if it is determined in operation 505 that the extracted flag has a value of 0, then it appears that the align bit array of the input bitstream does not include any information and is simply filled with one or more 0s or meaningless bits. Thus, in operation 540, the decoding unit 430 performs a decoding operation using the extracted data bit array only.

FIG. 6 is a block diagram of a multi-channel audio signal encoding/decoding system according to an embodiment of the present invention. Specifically, FIG. 6 illustrates an MPEG surround SAC encoding apparatus and an MPEG Surround SAC decoding apparatus.

Referring to FIG. 6, an encoding apparatus 600 includes a down-mix module which generates a down-mix signal by down-mixing a multi-channel audio signal to a stereo signal or a mono signal, and a spatial parameter estimation module which generates spatial information. The encoding apparatus 600 may receive an arbitrary artistic down-mix signal from an external device. A decoding apparatus 610 performs spatial synthesis on a plurality of pieces of spatial information, and restores an original multi-channel audio signal from an input down-mix signal through decoding according to the results of the spatial synthesis.

A multi-channel audio signal encoding method and apparatus and a multi-channel audio signal decoding method and apparatus according to the present invention can be applied to a multi-channel audio processing operation based on the MPEG Surround standard. However, the present invention is not restricted to this. In other words, the present invention can also be applied to various types of signal processing operations other than that set forth herein.

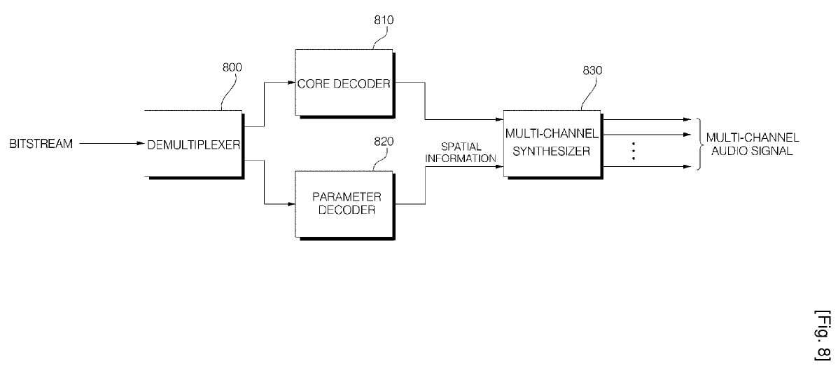

FIG. 7 is a block diagram of a multi-channel audio signal encoding apparatus according to an embodiment of the present invention. Specifically, FIG. 7 illustrates an MPEG Surround SAC encoding apparatus.

Referring to FIG. 7, the multi-channel audio signal encoding apparatus includes a down-mixer 700, a spatial parameter calculator 710, a core encoder 720, and a parameter encoder 730.

The down-mixer 700 down-mixes an input multi-channel audio signal, thereby generating a down-mix signal. For example, in the case of down-mixing a multi-channel audio signal having five channels to a stereo signal, down-mix channel 1 can be obtained by combining components of the first, third, and fourth channels of the multi-channel audio signal, and down-mix channel 2 can be obtained by combining components of the second, third, and fifth channels of the multi-channel audio signal.

The spatial information calculator 710 calculates spatial information. The spatial information includes a plurality of spatial parameters such as a channel level difference (CLD), inter-channel cross correlation (ICC), and channel prediction coefficient (CPC).

The core encoder 720 encodes the down-mix signal obtained by the down-mixer 700, and the parameter encoder 730 encodes the spatial information obtained by the spatial information calculator 710.

FIG. 8 is a block diagram of a multi-channel audio signal decoding apparatus according to an embodiment of the present invention. Specifically, FIG. 8 illustrates an MPEG Surround SAC decoding apparatus.

Referring to FIG. 8, the multi-channel audio signal decoding apparatus includes a demultiplexer 800, a core decoder 810, a parameter decoder 820, and a multi-channel synthesizer 830.

The demultiplexer 800 demultiplexes an encoded down-mix signal and encoded spatial information from an input bitstream. The core decoder 810 obtains a down-mix signal by decoding the encoded down-mix signal, and the parameter decoder 820 obtains spatial information by decoding the encoded spatial information. The multi-channel synthesizer 830 generates a multi-channel audio signal using the spatial information obtained by the parameter decoder 820 and the down-mix signal obtained by the core decoder 810.

The present invention can be realized as computer-readable code written on a computer-readable recording medium. The computer-readable recording medium may be any type of recording device in which data is stored in a computer-readable manner. Examples of the computer-readable recording medium include a ROM, a RAM, a CD-ROM, a magnetic tape, a floppy disc, an optical data storage, and a carrier wave (e.g., data transmission through the Internet). The computer-readable recording medium can be distributed over a plurality of computer systems connected to a network so that computer-readable code is written thereto and executed therefrom in a decentralized manner. Functional programs, code, and code segments needed for realizing the present invention can be easily construed by one of ordinary skill in the art.

### INDUSTRIAL APPLICABILITY

As described above, according to the present invention, it is possible to enhance the quality of decoded data by inserting various information into an align bit array that is included in a bitstream for aligning a plurality of encoded data bit arrays with one another. In addition, according to the present invention, it is possible to efficiently utilize data bandwidths that are allocated for the encoding/decoding of data at low bitrates by enhancing the efficiency of data encoding.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. An encoding method comprising:
encoding data;
generating a data bit array comprising the encoded data and encoding information; and
generating an align bit array comprising one or more 1s.

2. The encoding method of claim 1, wherein the align bit array comprises part of the encoded data that is not included in the data bit array.

3. The encoding method of claim 1, wherein the align bit array comprises additional information regarding the data bit array.

4. The encoding method of claim 1, wherein the align bit array comprises error check data which is needed to determine whether transmission errors regarding the data bit array and the align bit array have occurred.

5. A decoding method of receiving a bitstream and decoding the bitstream, the decoding method comprising:
extracting a data bit array comprising encoded data and encoding information from the bitstream;
extracting an align bit array comprising one or more 1s from the bitstream; and decoding the extracted data bit array using information included in the extracted align bit array.

6. The decoding method of claim 5, wherein the number of bits in the extracted align bit array is the same as a difference between the number of bits in the extracted data bit array and the number of bits allocated to the extracted data bit array.

7. The decoding method of claim 6, wherein the number of bits allocated to the extracted data bit array is a least multiple of 8 greater than the number of bits in the extracted data bit array.

8. The decoding method of claim 5, wherein the decoding comprises:
combining the extracted data bit array and the extracted align bit array; and
decoding a bit array obtained by the combining.

9. The decoding method of claim 5, wherein the decoding comprises:
decoding the extracted data bit array; and
acquiring additional information regarding encoded data obtained by the decoding of the extracted data bit array from the extracted align bit array.

10. The decoding method of claim 9, wherein the additional information comprises at least one of watermark data and metadata regarding the encoded data obtained by the decoding of the extracted data bit array.

11. The decoding method of claim 10, wherein the acquiring comprises:
combining the extracted align bit array and a previous align bit array that is extracted from a bitstream of a previous frame; and
decoding at least one of the watermark data and the metadata using an align bit array obtained by the combining.

12. The decoding method of claim 5, wherein the decoding comprises:
decoding the extracted data bit array; and
determining whether transmission errors have occurred during transmission of the bitstream based on error check data of the extracted align bit array.

13. The decoding method of claim 12, wherein the determining comprises:
obtaining first error check data corresponding to the number of bits in the extracted align bit array; and
comparing the first error check data with second error check data that is extracted from the extracted align bit array, and determining that transmission errors have occurred during the transmission of the bitstream if the first error check data and the second error check data do not match.

14. The decoding method of claim 5, wherein the decoding comprises:
decoding down-mix data and spatial information included in the extracted data bit array; and
generating multi-channel audio data using the decoded down-mix data and the decoded spatial information.

15. A decoding method of receiving a bitstream and decoding the bitstream, the decoding method comprising:
extracting a data bit array comprising encoded data and encoding information from the bitstream;
extracting a flag indicating whether an align bit array comprises information from the bitstream; and
if the flag has a value of 1, extracting an align bit array from the bitstream and decoding the extracted data bit array using information included in the extracted align bit array.

16. An encoding apparatus comprising:
an encoding unit which encodes data; and
a bitstream generation unit which generates a bitstream using the encoded data, wherein the bitstream generation unit comprises:
a data bit array generation unit which generates a data bit array comprising the encoded data and encoding information; and an align bit array generation unit which generates an align bit array comprising one or more 1s.

17. The encoding apparatus of claim 16, further comprising a storage unit which stores encoded data that is not included in the data bit array,
wherein the align bit array generation unit generates the align bit array using a predetermined amount of encoded data stored in the storage unit, the pre-determined amount corresponding to a predetermined align bit quantity.

18. The encoding apparatus of claim 16, further comprising a storage unit which stores additional information regarding the bitstream,
wherein the align bit array generation unit generates the align bit array using additional information that is stored in the storage unit and corresponds to a pre-determined align bit quantity.

19. The encoding apparatus of claim 16, further comprising a storage unit which respectively stores error check data in connection with a plurality of align bit quantities,
wherein the align bit array generation unit reads error check data corresponding to a predetermined align bit quantity from the storage unit.

20. A decoding apparatus of receiving a bitstream and decoding the bitstream, the decoding apparatus comprising:
a data bit array extraction unit which extracts a data bit array comprising encoded data and encoding information from the bitstream;
an align bit array extraction unit which extracts an align bit array comprising one or more 1s from the bitstream; and
a decoding unit which decodes the extracted data bit array using information included in the extracted align bit array.

21. The decoding apparatus of claim 20, wherein the number of bits in the extracted align bit array is the same as a difference between the number of bits in the extracted data bit array and a least multiple of 8 greater than the number of bits in the extracted data bit array.

22. The decoding apparatus of claim 20, wherein the decoding unit comprises:
a first decoder which obtains data by decoding the extracted data bit array; and
a second decoder which obtains additional information regarding the data by decoding the align bit array.

23. The decoding apparatus of claim 22, wherein the additional information comprises at least one of watermark data and metadata regarding the data.

24. The decoding apparatus of claim 20, wherein the decoding unit determines whether transmission errors regarding the bitstream have occurred based on error check data included in the extracted align bit array.

25. The decoding apparatus of claim 20, wherein the decoding unit comprises:
a core decoder which decodes encoded down-mix data included in the extracted data bit array;
a parameter decoder which decodes encoded spatial information included in the extracted data bit array; and
a multi-channel synthesizer which generates multi-channel audio data by combining the decoded down-mix data and the decoded spatial information.

26. A data structure of a bitstream comprising encoded data, the data structure comprising:
a frame data field which comprises the encoded data and encoding information as frames;
a byte align field which comprises an align bit array that comprises one or more 1s; and
a flag which indicates whether the align bit array comprises information.

27. A computer-readable recording medium having recorded thereon a program for executing the encoding method of claim 1.

28. A computer-readable recording medium having recorded thereon a program for executing the decoding method of claim 15.
